(19) United States
(12) Patent Application Publication
(10) Pub. No.: US 2024/0206173 A1
(43) Pub. Date: Jun. 20, 2024

(54) SEMICONDUCTOR DEVICE AND METHOD FOR MANUFACTURING SEMICONDUCTOR DEVICE

(71) Applicant: Kioxia Corporation, Tokyo (JP)

(72) Inventors: Shunsuke OKADA, Suzuka Mie (JP); Tatsunori ISOGAI, Yokkaichi Mie (JP)

(21) Appl. No.: 18/459,339

(22) Filed: Aug. 31, 2023

(30) Foreign Application Priority Data
Dec. 20, 2022 (JP) 2022-203500

(51) Int. Cl. H10B 43/27; H01L 29/66

(52) U.S. Cl. CPC H10B 43/27; H01L 29/66833

(57) ABSTRACT

According to one embodiment, a semiconductor device has a stack of first films and first insulating films stacked in a first direction. The first films include an electrode layer and a second insulating film on an upper face, a lower face, and a side face of the electrode layer. A semiconductor layer extends in the first direction. A charge accumulating layer is between the semiconductor layer and the film stack in a second direction and has first portions between the first films and the semiconductor layer and second portions between the first insulating films and the semiconductor layer. The first portions each have a first thickness in the second direction, and the second portions each have a second thickness less than the first in the second direction. First portions have a first width, and first films have a second width that is less than the first width.

### CROSS-REFERENCE TO RELATED APPLICATION (S)

This application is based upon and claims the benefit of priority from Japanese Patent Application No. 2022-203500, filed Dec. 20, 2022, the entire contents of which are incorporated herein by reference.

### FIELD

Embodiments described herein relate generally to a semiconductor device and a method for manufacturing a semiconductor device.

### BACKGROUND

An issue in the manufacturing of three-dimensional memory array chips is the characteristics of charge accumulating layers in the memory transistors.

### BRIEF DESCRIPTION OF THE DRAWINGS

FIG. 1 is a cross-sectional view of a semiconductor device according to a first embodiment.

FIG. 2 is an enlarged cross-sectional view of a semiconductor device according to a first embodiment.

FIGS. 3A and 3B are cross-sectional views illustrating aspects of a method for manufacturing a semiconductor device according to a first embodiment.

FIGS. 4A and 4B are cross-sectional views illustrating aspects of a method for manufacturing a semiconductor device according to a first embodiment.

FIGS. 5A and 5B are cross-sectional views illustrating aspects of a method for manufacturing a semiconductor device according to a first embodiment.

FIGS. 6A and 6B are cross-sectional views illustrating aspects of a method for manufacturing a semiconductor device according to a first embodiment.

FIGS. 7A and 7B are cross-sectional views illustrating aspects of a method for manufacturing a semiconductor device according to a first embodiment.

FIGS. 8A to 8C are cross-sectional views illustrating the certain aspects of a method for manufacturing a semiconductor device according to a first embodiment.

FIG. 9 is a cross-sectional view illustrating certain aspects of advantageous effects related to a semiconductor device according to a first embodiment.

FIG. 10 is a cross-sectional view illustrating a semiconductor device according to a comparative example.

FIG. 11 is an enlarged cross-sectional view illustrating the semiconductor device according to the comparative example.

FIGS. 12A and 12B are cross-sectional views illustrating aspects of a method for manufacturing the semiconductor device according to the comparative example.

FIG. 13 is a cross-sectional view illustrating a semiconductor device according to a second embodiment.

FIG. 14 is an enlarged cross-sectional view of a semiconductor device according to a second embodiment.

FIGS. 15A and 15B are cross-sectional views illustrating aspects of a method for manufacturing a semiconductor device according to a second embodiment.

### DETAILED DESCRIPTION

Embodiments provide a semiconductor device and a method for manufacturing the semiconductor device including a charge accumulating layer capable of achieving desired characteristics.

In general, according to one embodiment, a semiconductor device includes a film stack with first films and first insulating films alternatingly stacked in a first direction. The first films each include an electrode layer and a second insulating film disposed on an upper face, a lower face, and a side face of the electrode layer. A semiconductor layer extends in the first direction. A charge accumulating layer is between the semiconductor layer and the film stack in a second direction perpendicular to the first direction. The charge accumulating layer has first portions between the first films and the semiconductor layer in the second direction and second portions between the first insulating films and the semiconductor layer in the second direction. The first portions each have a first thickness in the second direction. The second portions each have a second thickness in the second direction. The second thickness is less than the first thickness. At least one of the first portions has a first width in the first direction, and at least one of the first films has a second width in the first direction. The second width is less than the first width.

Certain example embodiments will now be described with reference to the accompanying drawings. In the drawings, the same or substantially the same components are denoted by the same reference symbols and redundant description will be omitted.

### First Embodiment

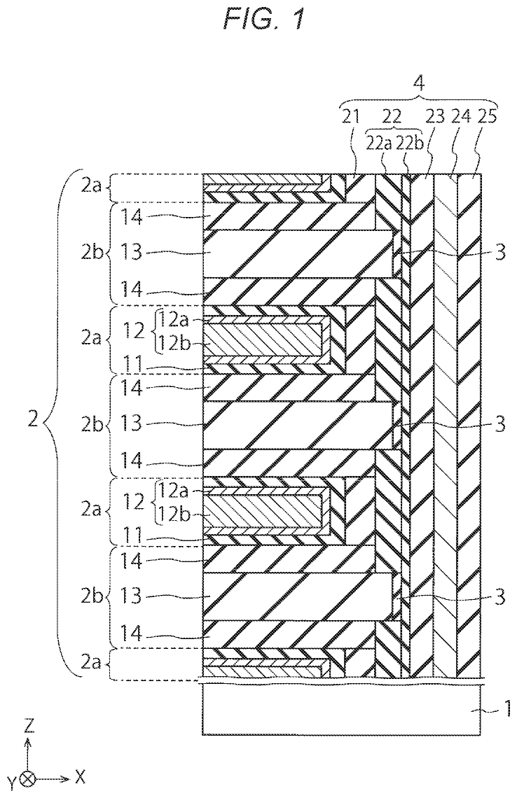

FIG. 1 is a cross-sectional view illustrating a structure of a semiconductor device according to a first embodiment. The semiconductor device according to the first embodiment includes a three-dimensional semiconductor memory array.

The semiconductor device according to the first embodiment includes a substrate 1, a film stack 2, multiple insulating films 3, and a pillar 4. The film stack 2 includes multiple films 2a and multiple films 2b. The films 2a each include a block insulating film 11 and an electrode layer 12. The electrode layer 12 of the film 2a includes a barrier metal layer 12a and an electrode material layer 12b. The films 2b each include an insulating film 13 and multiple insulating films 14. The pillar 4 includes multiple block insulating films 21, a charge accumulating layer 22, a tunnel insulating film 23, a channel semiconductor layer 24, and a core insulating film 25. The charge accumulating layer 22 (a charge storage layer) includes multiple outer peripheral charge accumulating layers 22a and an inner peripheral charge accumulating layer 22b. The film 2a is an example of the first film. The film 2b, the block insulating film 11, the block insulating film 21, the tunnel insulating film 23, the insulating film 13, and the insulating film 14 are examples of the first to six insulating films, respectively. The inner peripheral charge accumulating layer 22b and the outer peripheral charge accumulating layers 22a are examples of the first and second layers, respectively.

The substrate 1 is, for example, a semiconductor substrate such as a silicon (Si) substrate. FIG. 1 shows an X direction and a Y direction that are parallel to the surface of the substrate 1 and perpendicular to each other, and a Z direction orthogonal to the surface of the substrate 1. The X direction, the Y direction, and the Z direction are orthogonal to each other. In this specification, the positive Z direction is regarded as the upward direction, and the negative Z direction as the downward direction. The negative Z direction may or may not coincide with the direction of gravity. The Z direction is an example of the first direction. The X direction is an example of the second direction.

The film stack 2 is formed on the substrate 1 and alternatingly includes the films 2a and the films 2b stacked along the Z direction. The film stack 2 may be formed directly on the substrate 1 or with another film interposed between the film stack 2 and the substrate 1.

The films 2a each include an electrode layer 12 and the block insulating films 11 disposed on the upper face, the lower face, and a side face of the electrode layer 12. The block insulating film 11 is, for example, an aluminum oxide (Al₂O₃) film. The aluminum in the block insulating film 11 is an example of a metal element in the second insulating film. The electrode layer 12 includes the barrier metal layer 12a disposed on the upper face, the lower face, and the side face of the block insulating film 11 in sequence, and the electrode material layer 12b. The barrier metal layer 12a is, for example, a titanium nitride (TiN) film. The electrode material layer 12b is, for example, a tungsten (W) layer. The electrode layer 12 functions as a word line or a select line of the three-dimensional semiconductor memory.

The films 2b each include the insulating film 13, the insulating film 14 disposed on the upper face of the insulating film 13, and the insulating film 14 disposed on the lower face of the insulating film 13. Each of the insulating films 13 and 14 is, for example, a SiO₂ film.

The insulating films 3 are formed on side faces of the insulating films 13. The insulating films 3 are formed by separating an etching stopper film into multiple pieces, which will be described below. Each insulating film 3 is, for example, a SiO₂ film.

The pillar 4 is formed on the substrate 1 and inside the film stack 2. The pillar 4 is columnar in shape and extends in the Z direction. The pillar 4 includes the block insulating films 21, the charge accumulating layer 22, the tunnel insulating film 23, the channel semiconductor layer 24, and the core insulating film 25 that are disposed on a side face of the film stack 2 in sequence. The pillar 4 provides multiple memory cells of the three-dimensional semiconductor memory.

The block insulating films 21 are formed on side faces of the films 2a. Each of the block insulating film 21 is, for example, a SiO₂ film. The block insulating films 21 are each disposed between the two insulating films 14 neighboring each other in the Z direction.

The charge accumulating layer 22 includes the outer peripheral charge accumulating layers 22a disposed on side faces of the block insulating films 21 and the inner peripheral charge accumulating layer 22b. The inner peripheral charge accumulating layer 22b is disposed as a continuous film along the inner side faces of the outer peripheral charge accumulating layers 22a. Thus, the charge accumulating layer 22 has multiple thick portions (combined thicknesses of the inner peripheral charge accumulating layer 22b and an outer peripheral charge accumulating layer 221) generally next to the films 2a and multiple thin portions (just the thickness of the inner peripheral charge accumulating layer 22b) generally next to the films 2b. That is, the thick portions are at the same height position (level) as the films 2a, and the thin portions are at the same position level as the films 2b. The thick portions each include the outer peripheral charge accumulating layer 22a and the inner peripheral charge accumulating layer 22b while the thin portions include just the inner peripheral charge accumulating layer 22b from among the outer peripheral charge accumulating layer 22a and the inner peripheral charge accumulating layer 22b. The thick portion is disposed on a side face of a block insulating film 21 and the side faces of two insulating films 14 while the thin portion is disposed on a side face of an insulating film 3. The charge accumulating layer 22 is thus continuously disposed on side faces of the films 2a and 2b, with the block insulating films 21 being interposed between the charge accumulating layer 22 and the film 2a and the insulating films 3 being interposed between the charge accumulating layer 22 and the film 2b.

The outer peripheral charge accumulating layer 22a and the inner peripheral charge accumulating layer 22b are, for example, silicon nitride (SiN) films. In the first embodiment, the charge accumulating layer 22 further contains oxygen as impurities. In the first embodiment, the number of oxygen atoms in the charge accumulating layer 22 is 12% (atomic %) or less of the total number of silicon atoms, nitrogen atoms, and oxygen atoms in the charge accumulating layer 22. In other words, the charge accumulating layer 22 of the first embodiment has a ratio of the number of oxygen atoms to the total number of silicon atoms, nitrogen atoms, and oxygen atoms of 0.12 or less. This ratio can be analyzed by, for example, transmission electron microscopic energy-dispersive X-ray (TEM-EDX) spectroscopy. In the first embodiment, the charge accumulating layer 22 has an oxygen content of, for example, 1.0×10²¹ atoms/cm³ or less. The charge accumulating layer 22 can accumulate signal charges of the three-dimensional semiconductor memory. In the pillar 4, the outer peripheral charge accumulating layers 22a in different memory cells are not continuous with each other in the Z direction while the inner peripheral charge accumulating layer 22b in the memory cells is continuous in the Z direction.

The tunnel insulating film 23 is formed on a first side face of the charge accumulating layer 22. The tunnel insulating film 23 is, for example, a silicon oxynitride (SiON) film.

The channel semiconductor layer 24 is formed on a side face of the tunnel insulating film 23. The channel semiconductor layer 24 is, for example, a polysilicon layer. The channel semiconductor layer 24 is formed on the first side face of the charge accumulating layer 22, with the tunnel insulating film 23 being interposed therebetween. The channel semiconductor layer 24 functions as a channel of the three-dimensional semiconductor memory.

The core insulating film 25 is formed on a side face of the channel semiconductor layer 24. The core insulating film 25 is, for example, a SiO₂ film.

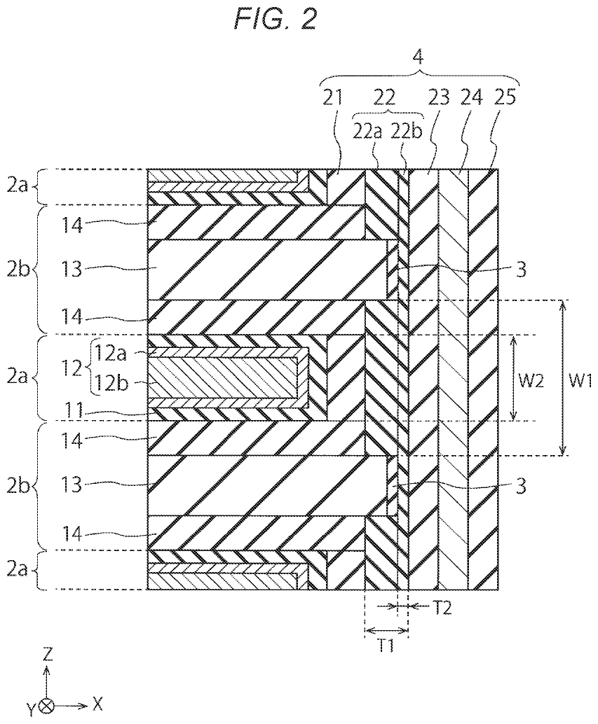

FIG. 2 is an enlarged cross-sectional view illustrating a structure of the semiconductor device according to the first embodiment.

The charge accumulating layer 22 has thick portions, with a large thickness T1, generally next to the films 2a in the X direction and thin portions, with a small thickness T2, generally next to the films 2b in the X direction. The thick portions each run over the outer peripheral charge accumulating layer 22a and the inner peripheral charge accumulating layer 22b, while the thin portions each run over only the inner peripheral charge accumulating layer 22b among the outer peripheral charge accumulating layer 22a and the inner peripheral charge accumulating layer 22b. The thickness T2 is less than the thickness T1 (T2<T1). The thick portion is an example of the first portion and the thin portion is an example of the second portion. The thickness T1 is an example of the thickness of the first film and the thickness T2 is an example of the thickness of the second film.

The thickness T1 refers to a dimension of the thick portion along a radial direction of the pillar 4. The thickness T2 refers to a dimension of the thin portion along a radial direction of the pillar 4. The central axis of the pillar 4 is shown in an X-Z cross-section in FIG. 2. Thus, in FIG. 2, the thickness T1 is the dimension of the thick portion in the X direction and the thickness T2 is the dimension of the thickness of the thin portion in the X direction.

FIG. 2 shows a width W1 of the thick portion of the charge accumulating layer 22 in the Z direction and a width W2 of each film 2a in the Z direction. In FIG. 2, the thick portion is disposed on side faces of one block insulating film 21 and two insulating films 14. The block insulating film 21 is disposed on a side face of one film 2a. Thus, the width W2 of the film 2a in the Z direction is less than the width W1 of the thick portion in the Z direction (W2<W1). The width W1 is an example of the first width and the width W2 is an example of the second width. The widths W1 and W2 in the first embodiment satisfy the condition of W2<W1≤2×W2.

It is noted that the width W1 may be a different value for the different thick portions of the charge accumulating layer 22 and/or that the width W2 may have a different value for the different films 2a. In this case, the relation of W2<W1 holds between each thick portion and film 2a disposed on a side face of the thick portion, that is, between the thick portion and the film 2a that correspond to each other. The relation of W2<W1 may or may not hold between all of the thin portions and the films 2a that correspond to each other and/or between some of the thick portions and the films 2a that correspond to each other.

The charge accumulating layer 22 according to the first embodiment includes the thick portions with the large thickness T1 and the thin portions with the small thickness T2. Thus, each thick portion can accumulate signal charges of a memory cell to suppress escape of the signal charges of the memory cell out of the charge accumulating layer 22 or into another memory cell.

In this case, the erasure characteristics of the memory cell may be reduced due to the small thickness T2 of the thin portion. Fortunately, the thick portion according to the first embodiment has the width W1 greater than the width W2 of the film 2a. Thus, the large width W1 of the thick portion and the small width of the thin portion can serve to mitigate a reduction in erasure characteristics otherwise due to the thin portion.

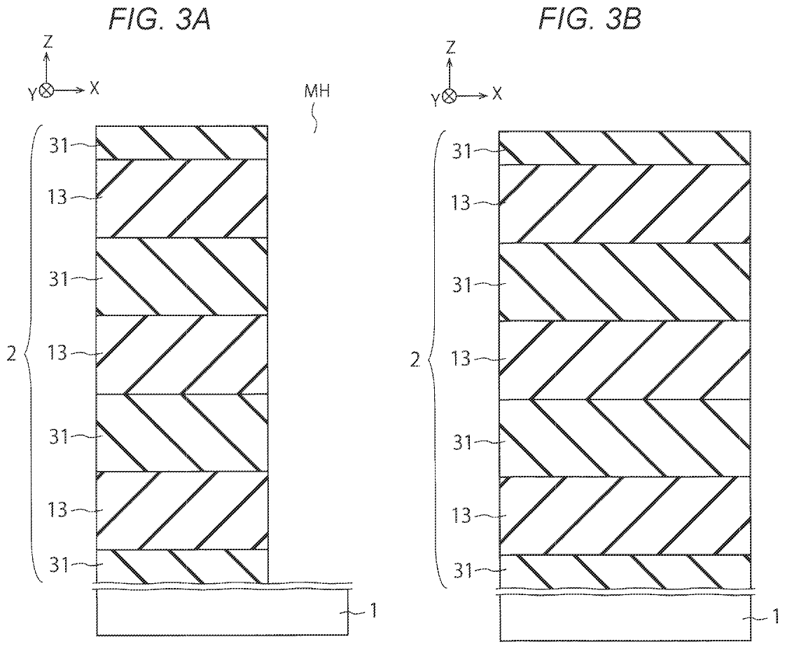

FIGS. 3A to 7B are cross-sectional views illustrating a method for manufacturing the semiconductor device according to the first embodiment.

Initially, a substrate 1 is prepared for formation of a film stack 2 on a substrate 1 (see FIG. 3A). The film stack 2 includes multiple sacrificial layers 31 and multiple insulating films 13 alternatingly stacked in the Z direction. The film stack 2 is formed by alternatingly stacking the sacrificial layers 31 and the insulating films 13 on the substrate 1. The film stack 2 may be formed directly on the substrate 1 or with another film interposed between the film stack 2 and the substrate 1. The sacrificial layers 31 are, for example, SiN films. The sacrificial layers 31 are an example of the second film.

Multiple memory holes MH are subsequently made in the film stack 2 by lithography and reactive ion etching (RIE) (see FIG. 3B). FIG. 3B illustrates one of the memory holes MH. The memory holes MH are each columnar in shape, extend in the Z direction, and are circular in shape in plan view.

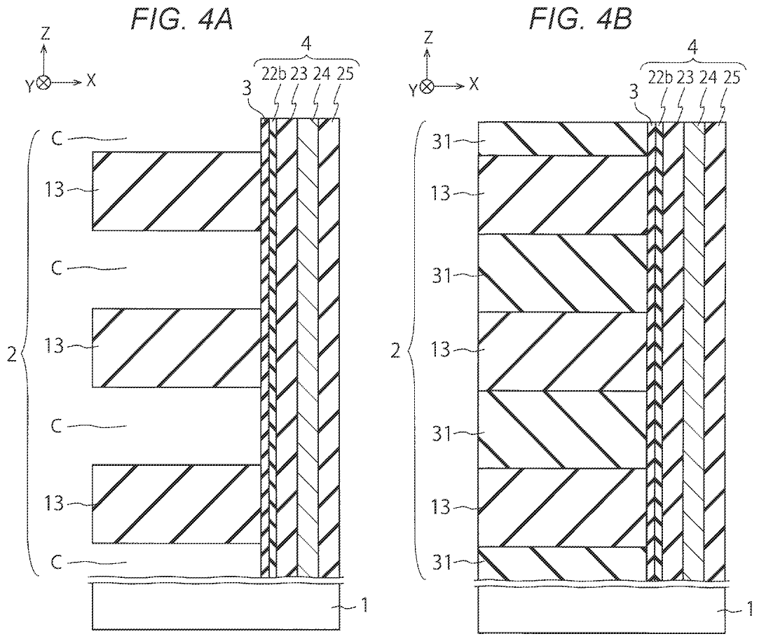

An insulating film 3, an inner peripheral charge accumulating layer 22b, a tunnel insulating film 23, a channel semiconductor layer 24, and a core insulating film 25 are subsequently formed, in sequence, on a side face of the film stack 2 in the memory hole MH (see FIG. 4A). As a result, a partial pillar 4 is formed in the memory hole MH. The insulating film 3, the inner peripheral charge accumulating layer 22b, the tunnel insulating film 23, the channel semiconductor layer 24, and the core insulating film 25 are formed, in sequence, on side faces of the sacrificial layers 31 and the insulating films 13. The insulating film 3 has a thickness of about 2 nm. The inner peripheral charge accumulating layer 22b has a thickness of about 2 In the first embodiment, the thickness of the inner peripheral charge accumulating layer 22b is set to a thickness T2. The tunnel insulating film 23 has a thickness of about 5 nm. The channel semiconductor layer 24 has a thickness of about 5 nm. The core insulating film 25 has a thickness of about 2 nm.

Multiple vertical slits are formed in the film stack 2 to permit removal of the sacrificial layers 31 by a chemical solution, such as a phosphoric acid solution, entering from the slits (see FIG. 4B). As a result, multiple recesses C are formed in the film stack 2. The recesses C are an example of a first recess.

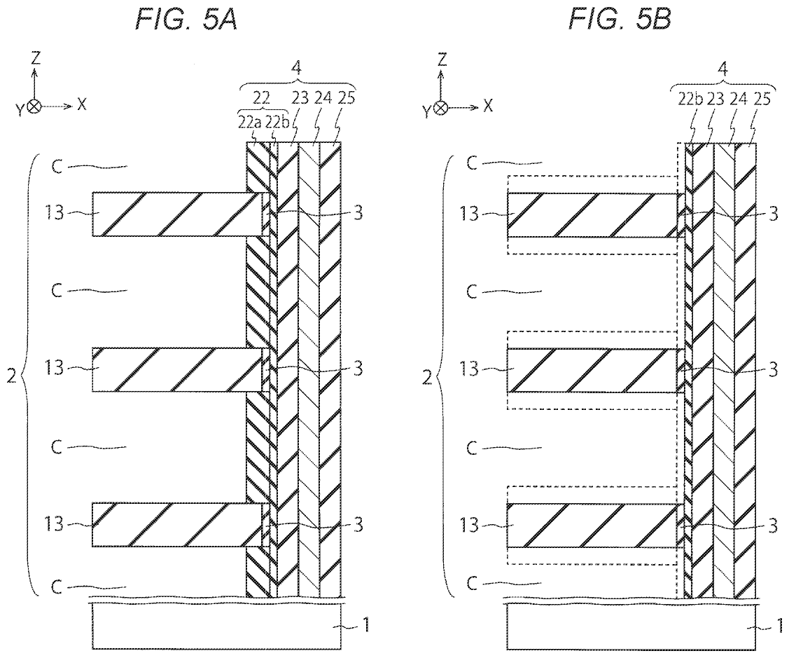

The insulating film 3 exposed in each recess C is subsequently removed by wet etching (see FIG. 5A). As a result, the insulating film 3 is separated into multiple insulating films 3 remaining on side faces of the insulating films 13. Furthermore, the insulating films 13 forming the upper and lower faces of the recess C are etched by wet etching such that the thicknesses of the insulating films 13 in the Z direction are reduced. FIG. 5A illustrates the shapes of the insulating films 3 and 13 before wet etching with a dashed line. The wet etching uses, for example, a chemical solution, such as a hydrofluoric acid solution.

The inner peripheral charge accumulating layer 22b exposed in the recess C is next pretreated for formation of an outer peripheral charge accumulating layer 22a on a side face of the inner peripheral charge accumulating layer 22b in the recess C (see FIG. 5B). The outer peripheral charge accumulating layer 22a according to the first embodiment is formed by selective growth from the side face of the inner peripheral charge accumulating layer 22b in the recess C. As a result, the outer peripheral charge accumulating layer 22a according to the first embodiment is selectively formed on the side face of the inner peripheral charge accumulating layer 22b, among the side face of the inner peripheral charge accumulating layer 22b and the upper and lower faces of the insulating films 13 and 3 in the recess C. In other words, the outer peripheral charge accumulating layer 22a according to the first embodiment is selectively formed on a side face of the recess C among the faces thereof. The additional aspects of such selective growth will be described below.

In the step of FIG. 5B, the charge accumulating layer 22 including the inner peripheral charge accumulating layer 22b and the outer peripheral charge accumulating layers 22a is formed in the pillar 4. As a result, the charge accumulating layer 22 has multiple thick portions, with a large thickness T1, lateral to the recesses C and multiple thin portions, with a small thickness T2, lateral to the insulating films 13. Furthermore, the thick portions of the charge accumulating layer 22 have a width W1 in the Z direction. It is noted that the inner peripheral charge accumulating layer 22b is pretreated for removal of a naturally oxidized film from the side face, exposed laterally to the recesses C, of the inner peripheral charge accumulating layer 22b. This can suppress inhibition of the selective growth by the naturally oxidized film.

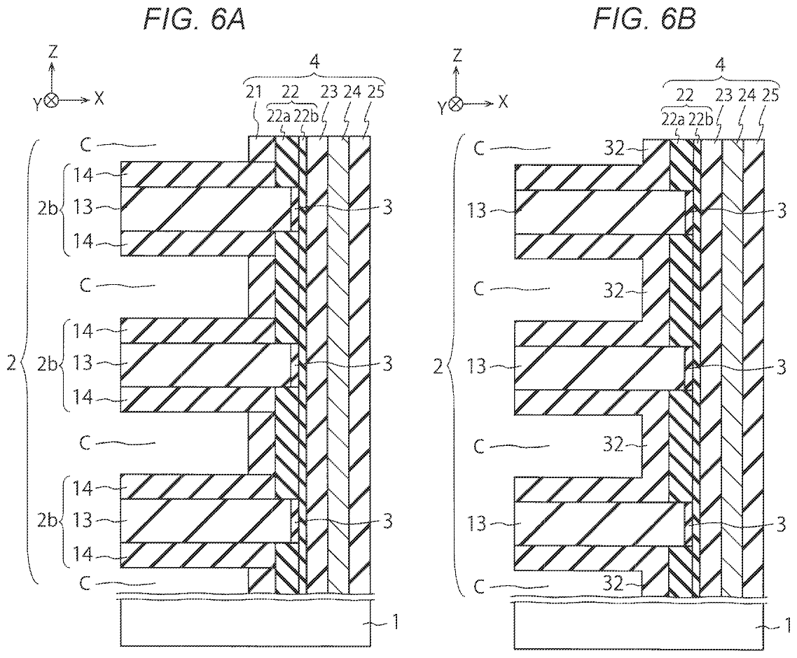

A cap insulating film 32 is subsequently formed on a second side face of the charge accumulating layer 22 and the upper face of a first insulating film 13 and the lower face of a second insulating film 13 in each recess C (see FIG. 6A). The cap insulating film 32 is, for example, a SiN film. The cap insulating film 32 is an example of the seventh insulating film. In the first embodiment, the pretreatment of the inner peripheral charge accumulating layer 22b, the selective growth of the outer peripheral charge accumulating layer 22a and the formation of the cap insulating film 32 are performed in situ (e.g., without removal from the process chamber). This can suppress formation of a naturally oxidized film on the side face of the outer peripheral charge accumulating layer 22a.

The cap insulating film 32 in the recess C is subsequently oxidized (see FIG. 6B). As a result, the cap insulating film 32 (SiN film) in the recess C is converted into a SiO₂ film. The SiO₂ film is formed into one block insulating film 21 and two insulating films 14 in the recess C. The block insulating film 21 is formed on the second side face of the charge accumulating layer 22. The insulating films 14 are formed on the lower face, forming the upper face of the recess C, of the first insulating film 13 and the upper face, forming the lower face of the recess C, of the second insulating film 13, respectively. It is noted that, although 6B illustrates a boundary between the block insulating film 21 and the insulating films 14 in the recess C for clarity of description, both the block insulating film 21 and the insulating films 14 in the recess C can be portions of the same SiO₂ film and that such a boundary need not be present or distinct.

In the step of FIG. 6B, the content of oxygen atoms (impurity atoms) in the charge accumulating layer 22 is decreased by oxidation of the cap insulating film 32. Thus, the charge accumulating layer 22 according to the first embodiment is converted into a SiN layer with a low content of oxygen atoms (as impurity atoms). In the first embodiment, the number of oxygen atoms in the charge accumulating layer 22 is 12% (atomic %) or less of the total number of silicon atoms, nitrogen atoms, and oxygen atoms in the charge accumulating layer 22. When the outer peripheral charge accumulating layer 22a has an oxygen content different from that of the inner peripheral charge accumulating layer 22b, the condition of 12% or less may hold for both or either of the outer peripheral charge accumulating layer 22a and the inner peripheral charge accumulating layer 22b.

It is noted that the step of FIG. 6B may be performed to oxidize only a portion of the cap insulating film 32 in the recess C. In this case, the cap insulating film 32 of SiN remains as a portion of the outer peripheral charge accumulating layer 22a, so that the thickness T1 of each thick portion increases. Alternatively, the step of FIG. 6B may be performed to oxidize not only the cap insulating film 32 but also a portion of the outer peripheral charge accumulating layer 22a in the recess C. In this case, the outer peripheral charge accumulating layer 22a of SiO₂ becomes portions of the block insulating film 21 and the insulating films 14, so that the thickness T1 decreases. After the step of FIG. 6A, a treatment for modifying the cap insulating film 32 may be performed. After the step of FIG. 6B, a treatment for modifying the block insulating film 21 and the insulating films 14 may be performed. Instead of the steps of FIGS. 6A and 6B, a SiO₂ film that is converted into the block insulating film 21 and the insulating films 14 may be formed in the recess C by chemical vapor deposition (CVD).

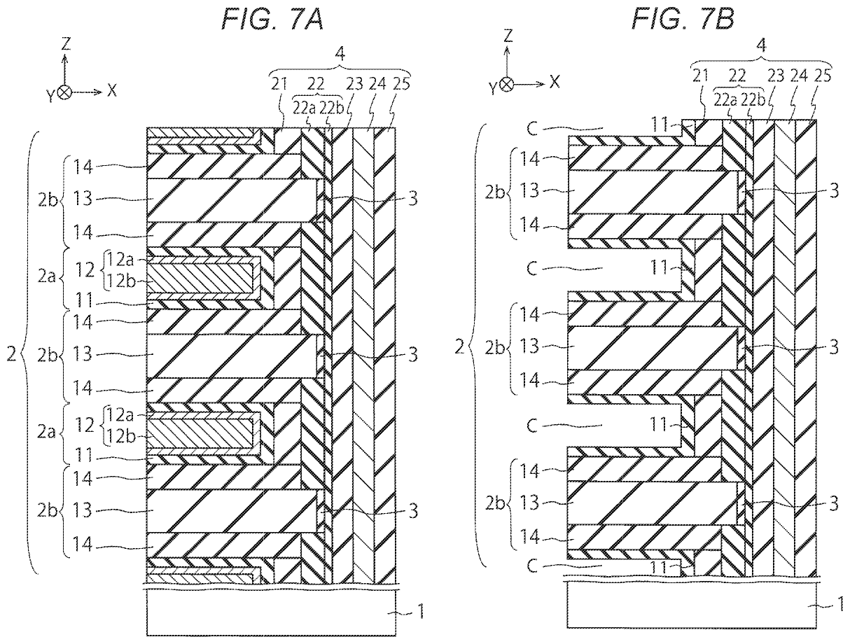

A block insulating film 11 is subsequently formed on the block insulating film 21 and the insulating films 14 in the recess C (see FIG. 7A).

A barrier metal layer 12a and an electrode material layer 12b are subsequently formed in sequence on the block insulating film 11 in the recess C (see FIG. 7B). As a result, an electrode layer 12 is formed with the block insulating film 11 therearound in the recess C. In this manner, a film stack 2 including multiple films 2a and multiple films 2b are formed on the substrate 1. Each film 2a is formed so as to include the block insulating film 11 and the electrode layer 12. Each film 2b is formed so as to include the insulating films 13 and 14. Since the insulating films 14 are formed in the recess C in the first embodiment, a width W2 of the film 2a in the Z direction is less than a width W1 of the thick portion of the charge accumulating layer 22 in the Z direction.

Thereafter, various layers, such as a wiring layer, a plug layer, and an interlayer insulating film, are formed on the substrate 1. In this manner, the semiconductor device illustrated in FIGS. 1 and 2 is manufactured.

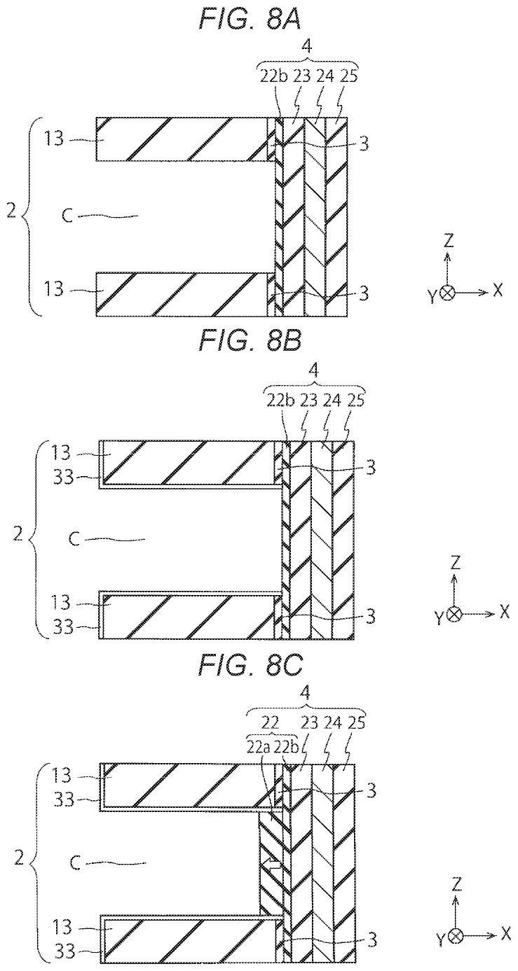

FIGS. 8A to 8C are cross-sectional views illustrating the details of the method for manufacturing the semiconductor device according to the first embodiment.

FIG. 8A is a partial view of FIG. 5A. In the first embodiment, before formation of the outer peripheral charge accumulating layer 22a (e.g., a SiN layer) on the side face of the inner peripheral charge accumulating layer 22b (e.g., a SiN layer) in the recess C, an inhibitor may be applied onto the insulating films 13 and 3 (e.g., SiO₂ films) (see FIG. 8B). As a result, inhibitor regions 33 are formed on the insulating films 13 and 3. The inhibitor regions 33 contain an inhibitor. In this context, an inhibitor is a substance that suppresses the adhering of a silicon precursor to the insulating films 13 and 3. In FIG. 8B, the inhibitor regions 33 are formed on the upper faces of first insulating films 13 and 3 and the lower faces of second insulating films 13 and 3 in the recess C, and side faces of the first and second insulating films 13 external to the recess c.

The silicon precursor is subsequently used for formation of the outer peripheral charge accumulating layer 22a on a side face of the inner peripheral charge accumulating layer 22b in the recess C (see FIG. 8C). Since the inhibitor regions 33 are formed on the insulating films 13 and 3 in FIG. 8C, the silicon precursor preferentially adheres to the side face of the inner peripheral charge accumulating layer 22b and is unlikely to adhere to the insulating film 13 and the insulating film 3. Thus, the first embodiment can selectively form the outer peripheral charge accumulating layer 22a on the side face of the inner peripheral charge accumulating layer 22b among the side face of the inner peripheral charge accumulating layer 22b and the upper faces of the first insulating films 13 and 3 and the lower faces of the second insulating films 13 and 3 in the recess C.

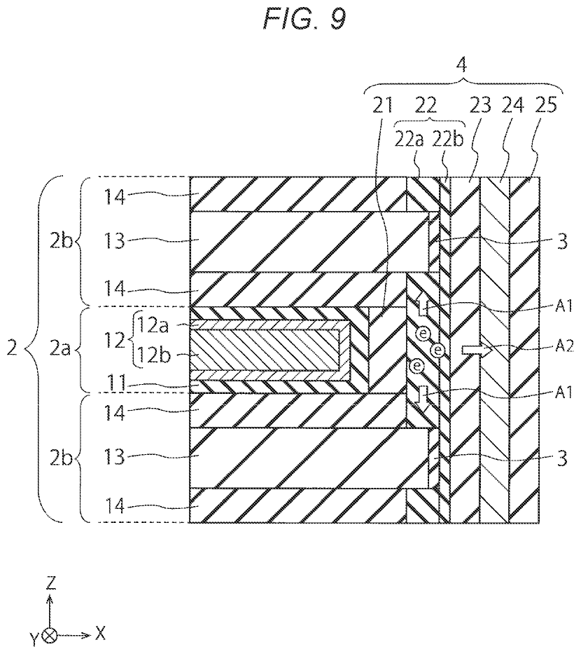

FIG. 9 is a cross-sectional view illustrating advantageous effects of the semiconductor device according to the first embodiment.

As illustrated in FIG. 9, the signal charges of each memory cell are accumulated in the charge accumulating layer 22 in the memory cell. The signal charges of the memory cell may escape into another memory cell as indicated by arrows A1 (vertical escape) or out of the charge accumulating layer 22 as indicated by an arrow A2 (horizontal escape). Fortunately, the charge accumulating layer 22 according to the first embodiment has the thick portions with the thickness T1 and the thin portions with the thickness T2. Thus, each thick portion can accumulate the signal charges of a memory cell to suppress escape of the signal charges from the memory cell into another memory cell or out of the charge accumulating layer 22. For example, the small thickness T2 of the thin portion hinders passage of the signal charges through the thin portion and can thus effectively suppress horizontal escape of the signal charges.

In this case, the erasure characteristics of the memory cell may be reduced due to the small thickness T2 of the thin portion. This is because the small thickness T2 of the thin portion hinders passage of the signal charges targeted for erasure through the thin portion. Fortunately, the thick portion according to the first embodiment has the width W1 greater than the width W2 of the film 2a. Thus, the large width W1 of the thick portion and the small width of the thin portion can suppress a reduction in erasure characteristics otherwise due to the thin portion. This is because the small width of the thin portion facilitates passage of the signal charges targeted for erasure through the thin portion. Thus, in the first embodiment, the width of the thin portion is preferably adjusted to a desired value for suppression of the horizontal escape and a reduction in erasure characteristics.

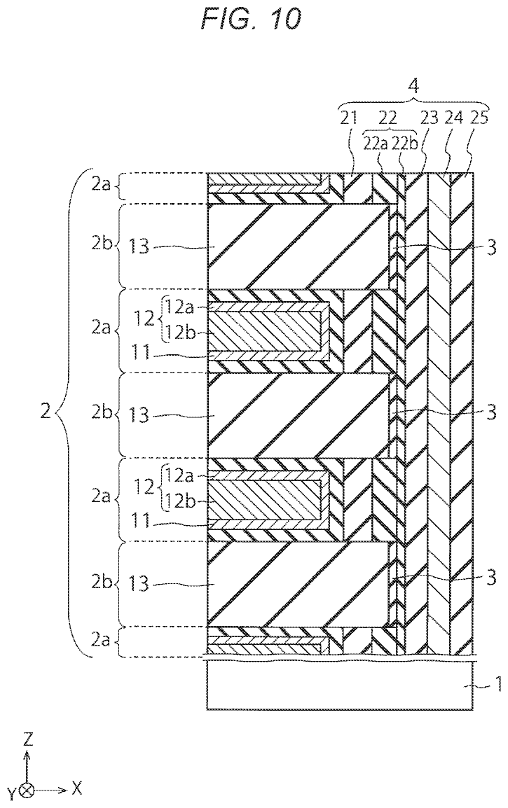

FIG. 10 is a cross-sectional view showing a structure of a semiconductor device according to a comparative example differing from the first embodiment.

Although the semiconductor device of the present comparative example depicted in FIG. 10 has a structure similar to that of the semiconductor device according to the first embodiment in FIG. 1, the films 2b in comparative example do not include insulating films 14. As a result, the charge accumulating layer 22 of the comparative example has a shape different from that of the charge accumulating layer 22 in the first embodiment. Additional aspects related to this difference will be described below.

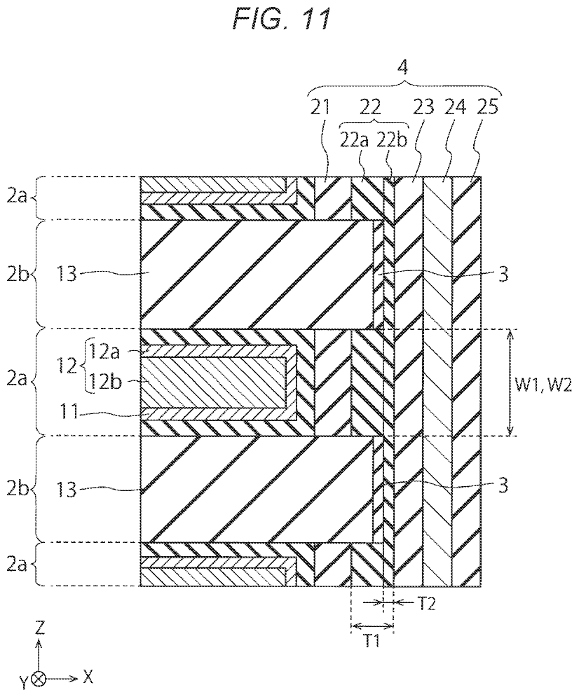

FIG. 11 is a cross-sectional view illustrating the structure of the semiconductor device according to the comparative example.

Although the charge accumulating layer 22 in the comparative example has multiple thick portions with a large thickness T1 and multiple thin portions with a small thickness T2, similar to the charge accumulating layer 22 in the first embodiment, the film 2b in the comparative example includes no insulating films 14. Thus, the thick portions are each disposed on a side face of a block insulating film 21. The block insulating film 21 is disposed on a side face of a film 2a. Thus, in the comparative example, a width W2 of the film 2a in the Z direction is equal to a width W1 of the thick portion in the Z direction.

In this case, the erasure characteristics of each memory cell may be reduced due to the small thickness T2 of the thin portion. This is because the small thickness T2 of the thin portion hinders passage of the signal charges targeted for erasure through the thin portion. A large width of the thin portion also hinders passage of the signal charges targeted for erasure through the thin portion. In contrast, the thin portion in the first embodiment has a small width and thereby facilitates passage of the signal charges targeted for erasure through the thin portion. Thus, the first embodiment can avoid a reduction in erasure characteristics otherwise caused due to the thin portion.

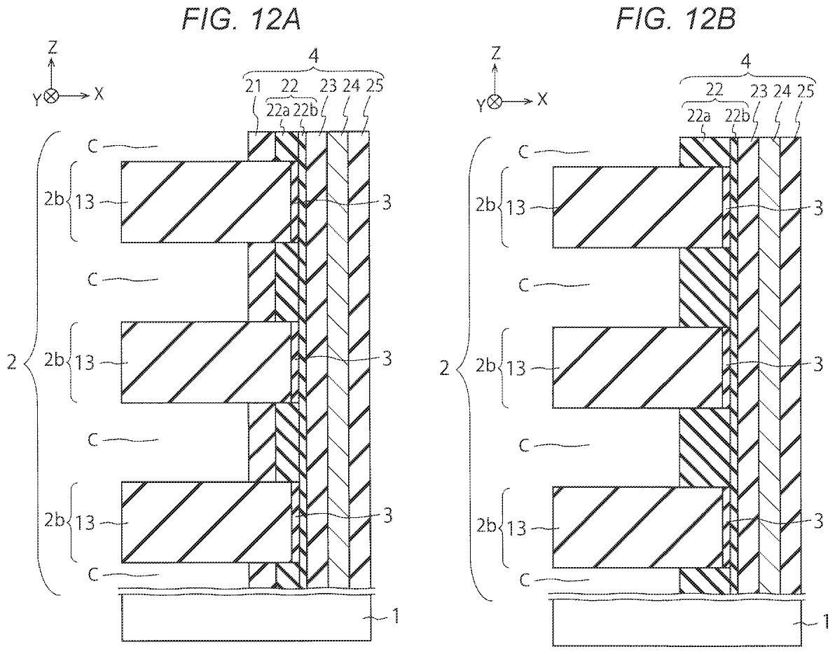

FIGS. 12A and 12B are cross-sectional views illustrating a method for manufacturing the semiconductor device according to the comparative example.

The cross-sectional view of FIG. 12A corresponds in general to that of FIG. 5A. In the comparative example, the thickness of each outer peripheral charge accumulating layer 22a is large, as illustrated in FIG. 12A. A portion of the outer peripheral charge accumulating layer 22a is oxidized to converted into a block insulating film 21 (see FIG. 12B). This enables formation of the block insulating film 21 on a side face of the outer peripheral charge accumulating layer 22a without formation of the insulating films 14. A drawback in this case is a reduction in erasure characteristics of each memory cell due to the small thickness T2 and the large width of the thin portion, as described above. In addition, natural oxidization of the outer peripheral charge accumulating layer 22a may reduce the write characteristics of the memory cell.

In contrast, the first embodiment uses a pretreatment on the inner peripheral charge accumulating layer 22b, then selective growth of the outer peripheral charge accumulating layer 22a, and formation of the cap insulating film 32 in situ (see FIGS. 5B and 6A). This can suppress (avoid) the natural oxidization of the outer peripheral charge accumulating layer 22a that reduces the write characteristics of the memory cell. Furthermore, formation of the block insulating film 14 and the insulating film 14 from the cap insulating film 32 (see FIG. 6B) can reduce the width W2 of the film 2a in the Z direction compared to the width W1 of the thick portion in the z direction. This can suppress a reduction in erasure characteristics of the memory cell due to the thin portion.

As described above, the charge accumulating layer 22 according to the first embodiment has thick portions with a large thickness T1 and thin portions with a small thickness T2. The width W1 of each thick portion is greater than the width W2 of the film 2a. Thus, the first embodiment can provide a charge accumulating layer 22 having desired characteristics. For example, the first embodiment can provide a charge accumulating layer 22 that improves the erasure and write characteristics of a memory cell.

### Second Embodiment

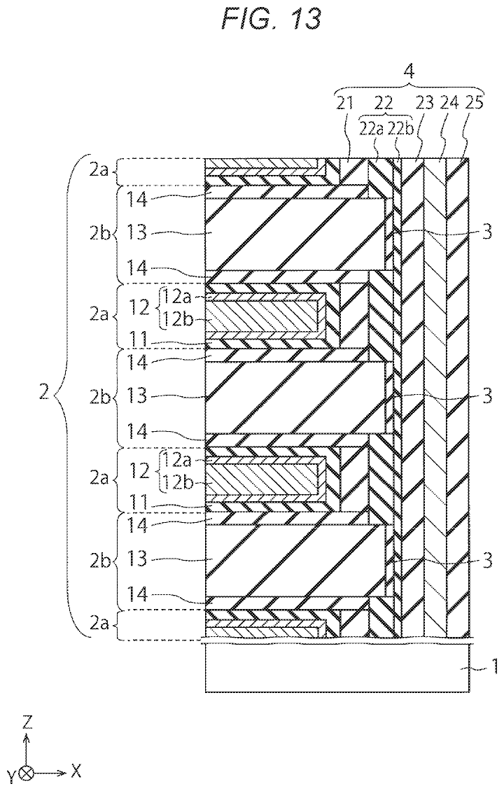

FIG. 13 is a cross-sectional view illustrating a structure of a semiconductor device according to a second embodiment.

Although the semiconductor device according to the second embodiment in FIG. 13 has a structure similar to that of the semiconductor device according to the first embodiment in FIG. 1, the difference between the widths W1 and W2 is large in the first embodiment while the difference between the widths W1 and W2 is small in the second embodiment.

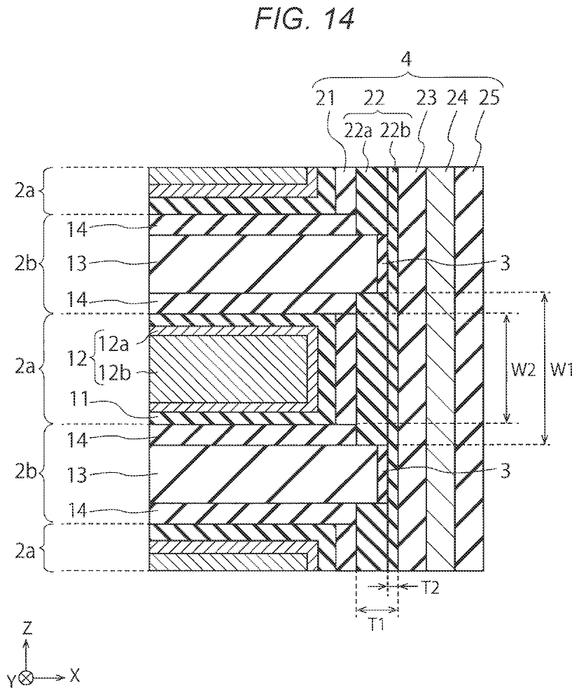

FIG. 14 is an enlarged cross-sectional view illustrating the structure of the semiconductor device according to the second embodiment.

The charge accumulating layer 22 according to the second embodiment has multiple thick portions with a large thickness T1 and multiple thin portions with a small thickness T2, similar to the charge accumulating layer 22 in the first embodiment. Thus, each thick portion can accumulate signal charges of a memory cell to suppress escape of the signal charges of the memory cell out of the charge accumulating layer 22 or into another memory cell.

In the second embodiment, a width W2 of each film 2a in the Z direction is less than a width W1 of the thick portion in the Z direction in the first embodiment. Thus, the large width W1 of the thick portion and the small width of the thin portion can avoid a reduction in erasure characteristics due to the thin portion.

While the difference between the widths W1 and W2 is large in the first embodiment, the difference between the widths W1 and W2 is small in the second embodiment. Thus, the first embodiment may have more substantial effects for avoiding a reduction in erasure characteristics while the second embodiment has more limited effects for avoiding a reduction in erasure characteristics. The shape of the charge accumulating layer 22 according to the second embodiment is preferably employed when the issue with a reduction in erasure characteristics is considered to be less serious or of less concern.

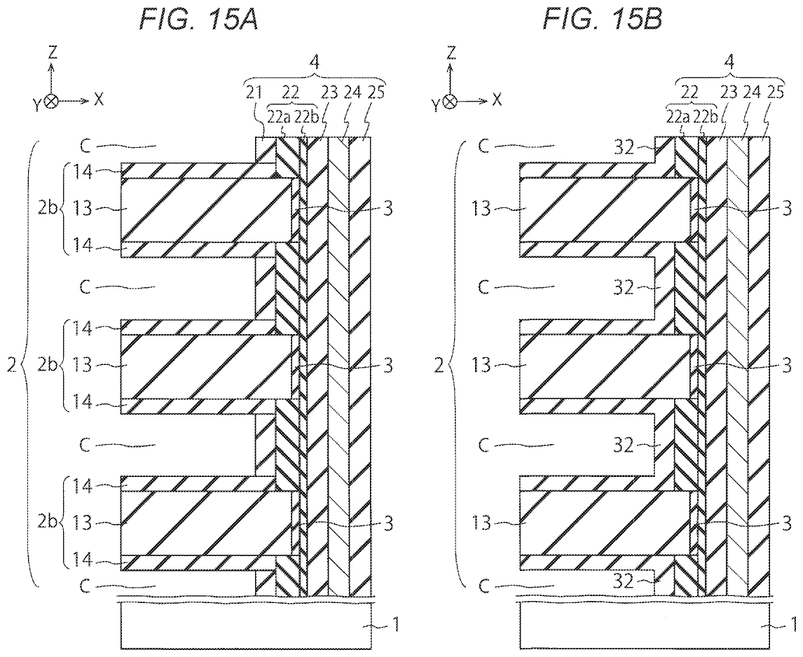

FIGS. 15A and 15B are cross-sectional views illustrating a method for manufacturing the semiconductor device according to the second embodiment.

Initially, the steps of FIGS. 3A to 6A are performed as in the first embodiment. The cross-sectional view of FIG. 15A corresponds in general to that of FIG. 6A. A cap insulating film 32 in each recess C is oxidized as in the step of FIG. 6B (see FIG. 15B). As a result, the cap insulating film 32 (e.g., a SiN film) in the recess C is converted into a SiO₂ film. The SiO₂ film is formed into one block insulating film 2 and two insulating films 14 in the recess C. Since the cap insulating film 32 has a small thickness in the second embodiment, the block insulating film 21 and the insulating films 14 also have small thicknesses.

The steps of FIGS. 7A and 7B are thereafter performed as in the first embodiment. In addition, various layers, such as a wiring layer, a plug layer, and an interlayer insulating film, are formed on a substrate 1. In this manner, the semiconductor device illustrated in FIGS. 13 and 14 is manufactured.

In the second embodiment, pretreatment of an inner peripheral charge accumulating layer 22b, selective growth of an outer peripheral charge accumulating layer 22a, and formation of the cap insulating film 32 are performed in situ as in the first embodiment. This can suppress formation of a naturally oxidized film on the side face of the outer peripheral charge accumulating layer 22a.

The charge accumulating layer 22 in the second embodiment has thick portions with a large thickness T1 and thin portions with a small thickness T2. The width W1 of the thick portion is greater than the width W2 of the film 2a. Thus, the second embodiment can provide the charge accumulating layer 22 having desired characteristics like the first embodiment. For example, the second embodiment can provide a charge accumulating layer 22 that improves the erasure and write characteristics of a memory cell.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a film stack including first films and first insulating films alternatingly stacked in a first direction, the first films each including an electrode layer and a second insulating film disposed on an upper face, a lower face, and a side face of the electrode layer;
a semiconductor layer extending in the first direction;
a charge accumulating layer between the semiconductor layer and the film stack in a second direction perpendicular to the first direction, the charge accumulating layer having first portions between the first films and the semiconductor layer in the second direction and second portions between the first insulating films and the semiconductor layer in the second direction, the first portions each having a first thickness in the second direction, and the second portions each having a second thickness in the second direction, the second thickness being less than the first thickness, wherein
at least one of the first portions has a first width in the first direction, and
at least one of the first films has a second width in the first direction, the second width being less than the first width.

2. The semiconductor device according to claim 1, wherein the first insulating films comprise silicon and oxygen.

3. The semiconductor device according to claim 1, wherein the second insulating film comprises a metal element.

4. The semiconductor device according to claim 3, wherein the metal element is aluminum.

5. The semiconductor device according to claim 1, further comprising:
third insulating films between each first portion and the first films in the second direction.

6. The semiconductor device according to claim 1, further comprising:
a fourth insulating film between the semiconductor layer and the film stack in the second direction, wherein
the fourth insulating film is a continuous film along the length of the semiconductor layer in the first direction.

7. The semiconductor device according to claim 1, wherein the charge accumulating layer comprises silicon and nitrogen.

8. The semiconductor device according to claim 7, wherein the charge accumulating layer further comprises oxygen.

9. The semiconductor device according to claim 8, wherein the number of oxygen atoms in the charge accumulating layer is 12% or less of the total number of silicon atoms, nitrogen atoms, and oxygen atoms in the charge accumulating layer.

10. The semiconductor device according to claim 1, wherein the charge accumulating layer is continuous along the length of the semiconductor layer in the first direction.

11. A method for manufacturing a semiconductor device, the method comprising:
forming a film stack including second films and fifth insulating films alternatingly stacked in a first direction;
forming a first layer of a charge accumulating layer on a side face of the film stack;
forming a semiconductor layer on a first side face of the first layer of the charge accumulating layer;
removing the second films from in the film stack to form first recesses in the film stack;
forming a second layer of the charge accumulating layer in each of the first recesses such that the charge accumulating layer has thick portions disposed lateral to the first recesses in a second direction orthogonal to the first direction and second portions disposed on side faces of the fifth insulating films, the thick portions each having a first thickness in the second direction, and the second portions each having a second thickness in the second direction, the second thickness being less than the first thickness;
forming a sixth insulating film in each of the first recesses; and
forming a first film in each first recess, the first film including a second insulating film and an electrode layer, wherein
at least one of the first portions is formed so as to have a first width in the first direction, and
at least one of the first films is formed so as to have a second width in the first direction, the second width being less than the first width.

12. The method according to claim 11, wherein the fifth insulating films and the sixth insulating film comprise silicon and oxygen.

13. The method according to claim 11, wherein the sixth insulating film is formed by forming a seventh insulating film comprising silicon and nitrogen in the first recess and converting the seventh insulating film into the sixth insulating film by oxidization.

14. The method according to claim 11, wherein the first layer is formed so as to have the second thickness.

15. The method according to claim 11, wherein the first layer is continuous along side faces of the second films.

16. The method according to claim 11, wherein the second layers are each selectively formed on a second side face of the first layer in the first recess.

17. The method according to claim 16, wherein the second layers are selectively formed on the second side face of the first layer after application of a material onto an upper face and a lower face of the first recesses.

18. The method according to claim 11, wherein the charge accumulating layer comprises silicon and nitrogen.

19. The method according to claim 18, wherein the charge accumulating layer further comprises oxygen.

20. The method according to claim 19, wherein the number of oxygen atoms in the charge accumulating layer is 12% or less of the total number of silicon atoms, nitrogen atoms, and oxygen atoms in the charge accumulating layer.
